(19) United States
(12) Patent Application Publication
(10) Pub. No.: US 2024/0420419 A1
(43) Pub. Date: Dec. 19, 2024

(54) METHOD FOR CREATING A THREE-DIMENSIONAL SOIL MODEL FOR A PLOT OF LAND

(71) Applicant: BAUER Spezialtiefbau GmbH, Schrobenhausen (DE)

(72) Inventors: Holger KAISER, Rostock (DE); Dominic HAIDACHER, Schrobenhausen (DE)

(73) Assignee: BAUER Spezialtiefbau GmbH, Schrobenhausen (DE)

(21) Appl. No.: 18/703,442

(22) PCT Filed: Nov. 22, 2022
(86) PCT No.: PCT/EP2022/082735

§ 371 Date: Apr. 22, 2024

(30) Foreign Application Priority Data
Dec. 6, 2021 (EP) 21 212 539.7

(51) Int. Cl. G06T 17/05; G06Q 30/0283; G06Q 50/08

(52) U.S. Cl. CPC G06T 17/05; G06Q 30/0283; G06Q 50/08

(57) ABSTRACT

The invention relates to a method for creating a three-dimensional soil model for a plot of land, particularly a building plot, wherein data is acquired in relation to a site plan of the plot, data is acquired in relation to a plurality of exploratory borings, which have been carried out on the plot at specific exploration points and for each exploratory boring a layer structure of the soil, with individual layers and their layer thickness, has been ascertained, and the individual exploration points are entered in the acquired site plan of the plot, wherein the individual layers for each exploratory boring are analyzed by means of a computer unit and are assigned in each case to a common soil layer, a layer thickness profile of the individual soil layers within the plot is interpolated depending on the position of the individual exploratory borings to one another, and the three-dimensional soil model for the plot is created by the computer unit in this way.

The invention relates to a method for creating a three-dimensional soil model for a plot of land, particularly a building plot, according to claim 1.

In building projects it is often necessary to prepare an excavation pit with soil excavation. The time and costs involved in soil excavation are largely dependent on the nature and structure of the soil at the construction site. In the case of larger building projects in particular, it is conventional or even necessary to prepare a geotechnical report before starting construction works.

Such a geotechnical report contains information about the structure of the soil. This information can be based on known values from plots in the vicinity of the building plot or on one or more exploratory borings.

The effort required for preparing an excavation pit is usually estimated based on the geotechnical report. This estimate is made on the basis of empirical values which are taken as a basis by an experienced specialist and planner when calculating the effort.

Even in use of experienced specialists, such estimates of the work and costs effort are very time-consuming and are associated with residual inaccuracies.

The object underlying the invention is to specify a method which enables to prepare information about a building plot in a particularly efficient and reliable manner.

The object is achieved by means of a method having the features of claim 1. Preferred embodiments are specified in the dependent claims.

The invention relates to a method for creating a three-dimensional soil model for a plot of land, particularly a building plot, wherein data is acquired in relation to a site plan of the plot of land, data is acquired in relation to a plurality of exploratory borings, which have been carried out on the plot of land at specific exploration points and for each of exploratory borings a layer structure of the soil, with individual layers and their layer thickness, has been ascertained, the individual exploration points are entered in the acquired site plan of the plot of land, wherein the individual layers for each exploratory boring are analyzed by means of a computer unit and are assigned in each case to a common soil layer, a layer thickness profile of the individual soil layers within the plot of land is interpolated depending on the position of the individual exploratory borings to each other, and the three-dimensional soil model for the plot of land is created by the computer unit in this way.

The method according to the invention uses a computer unit, which is configured to receive and to process acquired data relating to a site plan of the plot and data relating to sooner exploratory borings with information obtained about the layer structure of the soil. The computer unit is configured with a corresponding program such that the exact position of the individual exploratory borings can be assigned to the stored site plan of the plot, wherein a corresponding topography can also be acquired. In particular, a substantially horizontal layer structure of the soil is assumed by the program logic of the computer unit, wherein a layer structure is interpolated for the individual exploratory borings, with information about layers at the respective depths in the soil over the entire area of the plot, wherein a three-dimensional soil model is created. Overall, a digital three-dimensional soil model can be obtained in this way which reproduces clearly a realistic structure of the soil. In principle, this enables faster and more accurate estimates for preparing an excavation pit in the ground to be made. In particular, virtually any calculations relating to groundwork that may be required possibly can be carried out simply and reliably.

A preferred development of the method according to the invention consist in that the computer unit is connected to a display device and is configured such that a layer structure of the soil is displayed in relation to desired locations or sections in the plot. This can be helpful for designers when planning and specifying construction works that are required, for preparing building foundations for example.

A further preferred embodiment of the invention consists in that the computer unit is configured to ascertain and to output, for a specified surface region in the plot, layer volumes and/or layer materials for specified excavation depths and/or specified layers, based on the soil model. A specified surface region for an excavation pit and an excavation depth can be entered into the computer unit using the keyboard, a cursor or in any other way. On the basis thereof, the excavation volume for the excavation pit as a whole or also for individual layers can be ascertained and indicated by the computer unit. This enables a very quick and very accurate cost calculation to be made when preparing an excavation pit or when carrying out other soil removal work, to produce foundation elements for example. Based on the information about the individual layers and the structure of the layers, concrete investigations about the individual layer materials can also be take place, for example when layers of clay, sand, gravel, etc., are present.

In a further preferred variant of the method according to the invention is provided that in addition to a surface area, the topography, in particular a profile of a surface edge, is also recorded when acquiring the site plan. Particularly in the case of building plots on steeply sloping terrain, individual layers in exploratory borings that are spaced apart from one another can be correlated in a realistic manner in this way. This helps to achieve a realistic calculation when preparing the excavation pit.

In principle, it is advantageous for data acquired in relation to the site plan of the plot and/or to the exploratory borings with the information about the layer structure to be supplied to the computer unit as digital data, in order to create the soil model. The data can thus be retrieved from databases or from corresponding data acquisition devices, by remote data retrieval, in particular and supplied to the computer unit.

Alternatively or optionally, in an advantageous variant of the invention is provided that data relating to the site plan of the plot and/or to the exploratory borings with the information about the layer structure is read from an analogue document, in particular a geotechnical report. In the case of larger building projects in particular, a geotechnical report will exist because this usually has to be submitted to the relevant building authority by a surveyor. All the data for creating a three-dimensional soil model is generally contained in such a geotechnical report, but it usually contains a large amount of additional data and information that is not needed for determining the three-dimensional soil model.

The computer unit is preferably equipped with software which automatically acquires the data relating to the building plot and the exploratory borings and processes the data in order to produce the three-dimensional soil model.

Particularly advantageously, according to a development of the invention, is that the data is read from an analogue document using a scanner and/or a data acquisition and/or digitization program. In many cases, the geotechnical report is not available or not entirely available in digital form but rather as a conventional document, for instance in paper form, as a PDF document or as another image document.

An analogue document can be read in using a scanner. Where necessary, the document can be converted into a machine-readable version using a data acquisition and/or digitization program. Particularly in the case of drawings relating to a plan of the plot and to the structure of the exploratory borings, numbers and standardized symbols relating to the soil type are used, so dimensional information relating to the plot and to the borings, with layer thicknesses and the type of layer material, can be easily acquired and converted into a machine-readable digital version. This data can then be readily recognized by the computer unit and used and processed, in order to create the soil model.

In principle, any data relating to the structure of the soil can be taken into consideration when creating the soil model. It is particularly advantageous, according to a development of the invention, for the exploratory borings to be carried out in the form of trial drillings and/or frame soundings. Specific data about layer thicknesses and the structure of the individual layers can be reliably obtained across the depth in this case.

A further particularly expedient embodiment of the invention resides in that costs per m³ for various types of layers, for excavation and/or disposal for example, are stored in the computer unit and that an expected cost expenditure for a specified excavation volume is determined by the computer unit.

This is a considerable advantage, especially when a construction is planned and/or in tendering preparation for civil engineering works. The fact that higher or lower costs per m³ for excavation and/or disposal are to be provided for certain types of soil in a layer can be taken into consideration here.

Moreover, according to a development of the method according to the invention, it is advantageous that suitable removal equipment and/or an amount of time needed for removal/excavation per m³ for various types of layers is/are stored in the computer unit and that an expected amount of time for the specified extraction volume is determined by the computer unit. For example, a soil layer containing rock material can only be worked with certain types of groundwork equipment, such as a rotary cutter, while looser soil types, such as sand or gravel, can be worked with simple and hence less expensive excavation equipment, such as grabs or drilling rigs. This has an effect on the processing time needed for excavating a corresponding m³ and on the costs incurred for this, since different equipment have different equipment hourly rates. Such equipment hourly rates and processing times per m³ for a certain type of soil can be stored in the computer unit in an appropriate memory module.

In addition to such data for workflow and cost planning, according to a further embodiment variant of the invention it is advantageous that a load-bearing capacity of specified foundation elements, such as foundation piles, or, in the case of a specified load-bearing capacity, a dimensioning of foundation elements is ascertained using the soil model. With the stored soil model, the computer unit can thus also make an assessment of which types of foundation elements are to be used, and in what size and/or to what depth foundation elements are to be configured. To this end, corresponding information relating to processing times, processing costs and necessary equipment can also be determined directly by the computer unit.

In particular, according to a development of the invention, it is advantageous that data relating to costs of foundation elements are stored in the computer unit and an automatic cost estimate for foundation elements that are to be produced is made using the soil model. This too is a considerable advantage when making a tender for civil engineering works on a plot.

The invention is explained in more detail below by reference to preferred exemplary embodiments, which are illustrated schematically in the drawings. In the drawings show:

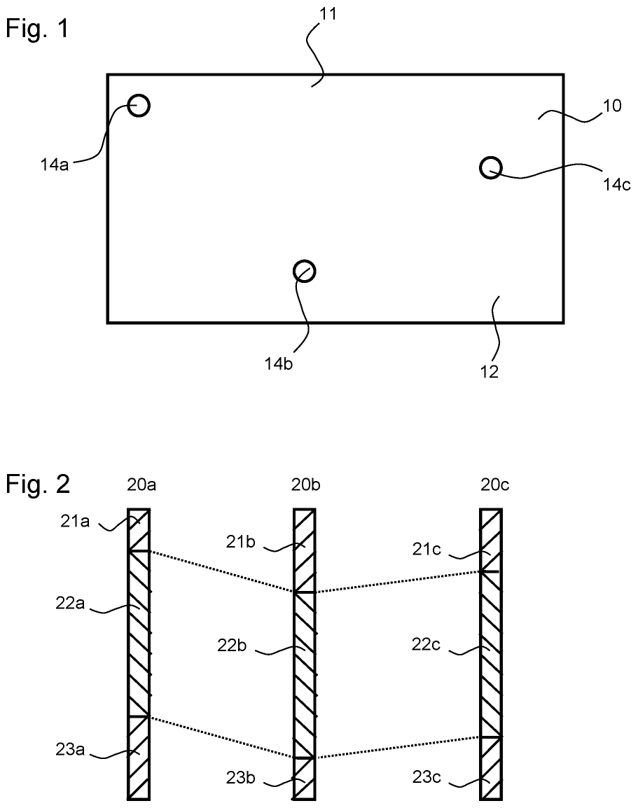

FIG. 1 a top view of a site plan of a plot of land;

FIG. 2 a schematic cross-sectional view of a layer structure in three spaced-apart exploratory borings with an interpolated layer profile; and

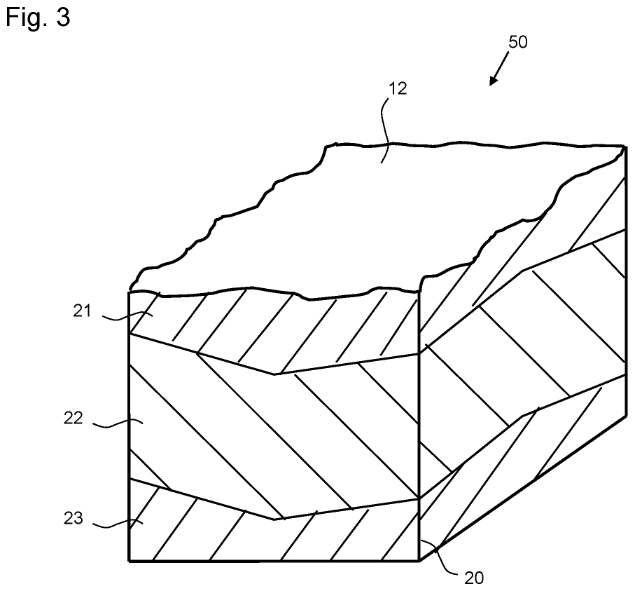

FIG. 3 an exemplary graphical representation of a three-dimensional soil model.

FIG. 1 shows schematicly a site plan 11 for a plot of land 10, in particular a building plot, in schematic form. The plot 10 can be provided with a topography 12 which is not even. By way of example, three exploration points 14a, 14b, 14c, which are spaced apart from one another and at which exploratory borings are carried out, are shown in the site plan 11.

FIG. 2 shows in each case a possible layer structure 20 at each exploration point 14, wherein layer structure 20a relates to the first exploration point 14a, layer structure 20b relates to the second exploration point 14b and the third layer structure 20c relates to the third exploration point 14c.

It can be seen from the respective layer structure 20 that in each case, down to a specified depth, the soil is built up of a first layer 21, a second layer 22 and a third layer 23. The thickness of the layers 21, 22, 23 in relation to the depth varies at the individual exploration points 14 from each other, as is clearly shown in FIG. 2. The layers 21, 22, 23 and the individual exploration points 14a, 14b, 14c are denoted in each case by designation a, b and c.

Based on this ascertained data relating to the layer structure 20 at the individual exploration points 14, a layer profile over the entire surface area of the plot 10 can be ascertained by a computer unit for the site plan 11. The computer unit is equipped in this case with a program which, on basis of the exploratory borings having in each case identified the respective layer structure 20a, 20b, 20c interpolates the profile of the layers and layer boundaries over the surface area of the plot, wherein preferably the layer boundaries at the exploration points 14 serve as reference points and a largely harmonious and/or horizontal layer profile is assumed in the calculation. It is clear that as the number of exploration points 14 and corresponding exploratory borings increases, the layer structure interpolated computationally by the computer unit becomes more realistic.

The computer unit, determines and generates a three-dimensional soil model 50 as a data model or computer model on the basis of the data that has been ascertained and entered in this way. A possible graphical representation of a three-dimensional soil model 50 is clearly illustrated in FIG. 3. The soil model 50 shows the plot 10 with an uneven topography 12 at the surface. Furthermore, a calculated layer thickness profile of the first layer 21, the second layer 22 and the third layer 23 is ascertained and displayed in accordance with the exploratory borings that were carried out.

Data relating to the dimensions of the plot, the exploratory borings and/or an excavation pit that is to be prepared can preferably be entered into the computer unit as or on the basis of GPS data.

Based on the data relating to a three-dimensional soil model 50 determined in this way, if corresponding dimensions for an excavation pit that is to be prepared or for other construction work in the ground are entered, realistic estimates of excavation volumes in individual layers as well as additional assessments can be made.

1.-12. (canceled)

13. A method for creating a three-dimensional soil model for a plot of land, particularly a building plot, wherein
data is acquired in relation to a site plan of the plot,
data is acquired in relation to a plurality of exploratory borings, which have been carried out on the plot at certain exploration points and for each exploratory boring a layer structure of the soil, with individual layers and their layer thickness, has been ascertained,
the individual exploration points are entered in the acquired site plan of the plot,
wherein the individual layers for each exploratory boring are analyzed and assigned in each case to a common soil layer by a computer unit,
a layer thickness profile of the individual soil layers within the plot is interpolated depending on the position of the individual exploratory borings to one another, and
the three-dimensional soil model for the plot is created by the computer unit in this way, and
wherein the computer unit is connected to a display device and is configured that a layer structure of the soil is displayed in relation to desired locations or sections in the plot.

14. The method according to claim 13,
wherein
the computer unit is configured to ascertain and to output, for a specifiable surface region in the plot, layer volumes and/or layer masses for specified excavation depths and/or specified layers, based on the soil model.

15. The method according to claim 13,
wherein
in addition to a surface area, also the topography, in particular a profile of a ground surface, is also acquired when acquiring the site plan.

16. The method according to claim 13,
wherein
data acquired in relation to the site plan of the plot and/or to the exploratory borings with the information about the layer structure is supplied as digital data to the computer unit, in order to create the soil model.

17. The method according to claim 13,
wherein
data relating to the site plan of the plot and/or to the exploratory borings with the information about the layer structure is read out from an analogue document, in particular a geotechnical report.

18. The method according to claim 17,
wherein
data is read out from an analogue document by using a scanner and/or a data acquisition and/or digitization program.

19. The method according to claim 13,
wherein
the exploratory borings are carried out as of trial drillings and/or frame soundings.

20. The method according to claim 13,
wherein
costs per cubic meter for various types of layers, for excavation and/or disposal for example, are stored in the computer unit and
an expected cost for a specified excavation volume is determined by the computer unit.

21. The method according to claim 13,
wherein
suitable removal equipment and/or an amount of time needed for removal/excavation per cubic meter for various types of layers is stored in the computer unit and
an expected amount of time for the specified extraction volume is determined by the computer unit.

22. The method according to claim 13,
wherein
a load-bearing capacity of specified foundation elements, such as foundation piles, or, in the case of a specified load-bearing capacity, a dimensioning of necessary foundation elements is ascertained by using the soil model.

23. The method according to claim 13,
wherein
data relating to costs of foundation elements is stored in the computer unit and an automatic cost estimate for foundation elements that are to be produced is made by using the soil model.
